(19) United States
(12) Patent Application Publication
(10) Pub. No.: US 2012/0126410 A1
(43) Pub. Date: May 24, 2012

(54) Contact Array for Substrate Contacting

(76) Inventors: Elke Zakel, Nauen (DE); Thorsten Teulsch, Santa Cruz, CA (US); Ghassem Azdasht, Berlin (DE)

(21) Appl. No.: 13/263,125

(22) PCT Filed: Nov. 5, 2009
(86) PCT No.: PCT/DE2009/001538

§ 371 Date: Dec. 16, 2011

(30) Foreign Application Priority Data
Apr. 8, 2009 (DE) 10 2009 016 594.0

(51) Int. Cl. H01L 23/485

(52) U.S. Cl. 257/758; 257/E29.019

(57) ABSTRACT

The present invention relates to a contact arrangement (47, 48, 49, 50, 55, 56, 57) for substrate contacting, in particular for contacting terminal faces of a semiconductor substrate (21), comprising at least one inner contact (25) of the contact arrangement that is formed on a substrate surface by a base terminal face of the substrate, a passivation layer (34, 35) covering at least the outer edge region and the periphery of the inner contact, at least one lower contact strip (36) extending laterally away from the inner contact (25) on the passivation layer (34, 35), and a further, upper contact strip (37, 38, 39) extending on the lower contact strip, wherein the further contact strip is formed by a contact metallization, which is substantially composed of a nickel (Ni) layer or a layer structure (38, 39) containing nickel and palladium (Pd).

The present invention relates to a contact arrangement for substrate contacting, in particular for contacting terminal faces of a semiconductor substrate, comprising at least one inner contact of the contact arrangement that is formed on a substrate surface by a base terminal face of the substrate, a passivation layer covering at least the outer edge region and the periphery of the inner contact, at least one lower contact strip extending laterally away from the inner contact on the passivation layer, and a further, upper contact strip extending on the lower contact strip, wherein the further contact strip is formed by a contact metallization, which is substantially composed of a nickel layer or a layer structure containing nickel and palladium.

Contact arrangements of the type mentioned above serve the purpose of forming outer terminal contact arrangements of a semiconductor substrate, by means of which the semiconductor substrate can be contacted with other semiconductor substrates or carrier substrates, such as printed circuit boards (PCB). In so-called chip size packages (CSP) such contact arrangements are directly formed on the surface of a chip which, in its blank state in which the chip for instance is provided by chip manufacturers, has terminal faces being made of aluminum and being directly disposed on a silicon body of the chip, which on its surface is furnished with a passivation covering the outer edge of the base terminal face to provide electrical insulation vis-à-vis the environment.

To form the outer terminal face arrangement, corresponding to the selected layout, by means of a contact arrangement extending from the base terminal faces, the contacts formed in the initial state by the base terminal faces are placed for instance in a central region or in a peripheral region of the chip surface for further contacting of the chip, such that the base terminal faces form inner contacts and the contacts formed by the contact arrangement form outer contacts being disposed on the surface of the semiconductor substrate.

In practical applications, it has emerged that functional failure of chips is frequently the result of flaws in the contact arrangements. Such flaws may be caused for instance due to corrosion effects or else due to insufficient mechanical adhesion between the layers of the contact arrangement being regularly configured as a layer structure, which ultimately leads to an increase in the contact resistances or to the creation of transition resistances in the contact arrangement.

It is an object of the present invention to suggest a contact arrangement that provides enhanced reliability with respect to the electric properties.

To attain this object the inventive contact arrangement exhibits the features of claim 1.

According to the invention, the contact arrangement comprises at least one lower contact strip which extends from the base terminal face on the passivation layer, and a further, upper contact strip which extends on the lower contact strip and is substantially composed of a nickel layer or a layer structure containing nickel and palladium.

In this way, according to the invention, a contact arrangement is provided, which, due to the second contact strip being composed of a nickel layer or a layer structure comprising nickel and palladium, for subsequent contacting of the contact arrangement with a further substrate provides a contact surface which exhibits particularly good adhesion and conductivity properties and which may serve, for instance directly with a solder material, for forming solder bumps, or which may also serve as a base for a further contact coating. Due to the strip-shaped design of the contact strip, the position of the contact surface with respect to a carrier substrate can be to freely selected. Depending on the configuration of the carrier substrate or the contact substrate, i.e. for instance in the case where the contact substrate to be contacted with the contact arrangement is sufficiently passivated, the application of a passivation layer on the contact arrangement, which defines the position of the contact surface on the contact arrangement or on the lower contact strip, can be omitted. In this way, using the inventive contact arrangement, it is possible, in particular, to produce a substrate arrangement with minimized thickness from the semiconductor substrate being furnished with the contact arrangement and from a carrier substrate being contacted with said semiconductor substrate via the contact arrangement.

In particular with respect to providing particularly good adhesion of the upper contact strip on the lower contact strip, it proves to be advantageous if the nickel layer or the layer structure containing nickel and palladium is formed by autocatalytic deposition of nickel or nickel and palladium, respectively. Beyond that, by means of forming the nickel layer or the layer structure containing nickel and palladium using autocatalytic deposition, the thickness of the deposited layer or of the deposited contact structure is particularly easy to control.

In a particularly advantageous embodiment the lower contact strip is composed of a contact metallization being substantially composed of a titanium, aluminum, copper or an aluminum-silicon alloy (AISi), an aluminum-silicon-copper alloy (AlSiCu) or a layer structure composed of titanium and an aluminum layer, a titanium layer and a layer composed of an aluminum-copper alloy or a titanium layer and a layer composed of an aluminum-silicon-copper alloy. In this context, it is particularly advantageous if the titanium layer in the layer structure respectively forms the lowermost layer.

In the case where the contact arrangement is intended to be used independently of the surface preparation of a carrier substrate to be contacted with the semiconductor substrate via the contact arrangement, according to a preferred embodiment, in order to form an outer contact of the contact arrangement, which is formed by a contact area of the upper contact strip, the upper contact strip except for the contact area can be covered by an outer passivation layer.

It is particularly advantageous, especially to facilitate production, if the outer passivation layer is composed of a dielectric layer essentially formed of BCB, PI, PBO, epoxy or a resist.

If the contact area of the upper contact strip is furnished with a contact coating having a layer structure composed of a nickel layer and a gold layer disposed thereon, for subsequent contacting with the aid of a solder material bump a particularly highly conductive and reliable sub-metallization is formed for the bump.

Concerning the formation of the contact coating, for achieving a particularly good adhesion between the layers and an accurate control of the layer thickness, it equally proves to be advantageous if the layer structure is formed by autocatalytic deposition or electroless deposition of nickel and gold.

Depending on the layout and topography of the connecting arrangement of the carrier substrate to be contacted with the semiconductor substrate via the contact arrangement, a differing configuration of the layer structure may prove to be advantageous. For instance, by making provision for a large solder material volume it may be advantageous if a contact surface which is offset with respect to the surface of the passivation layer is formed by means of the layer structure, such that a pocket-shaped receiving space is formed.

To form a particularly compact substrate arrangement from a semiconductor substrate and a carrier substrate which is contacted with the semiconductor substrate via the contact arrangement it may be advantageous if a contact surface being aligned with the passivation layer is formed by means of the layer structure.

To realize a defined gap between the semiconductor substrate and the carrier substrate being contacted with the semiconductor substrate via the contact arrangement it may be advantageous if a contact surface being formed by the surface of a contact metallization being raised with respect to the passivation layer is formed by means of the layer structure.

Depending on the composition of the solder bump used for contacting and the method used for contacting between the semiconductor substrate and the carrier substrate it may also be advantageous to provide a raised contact made of a solder material, i.e. a solder bump, directly on a contact area of the upper contact strip of the contact arrangement. Alternatively, it is also possible to form a contact coating of the type specified above between the contact area and the solder material.

Hereinafter advantageous embodiments will be explained in greater detail with reference to the drawings.

In the drawings:

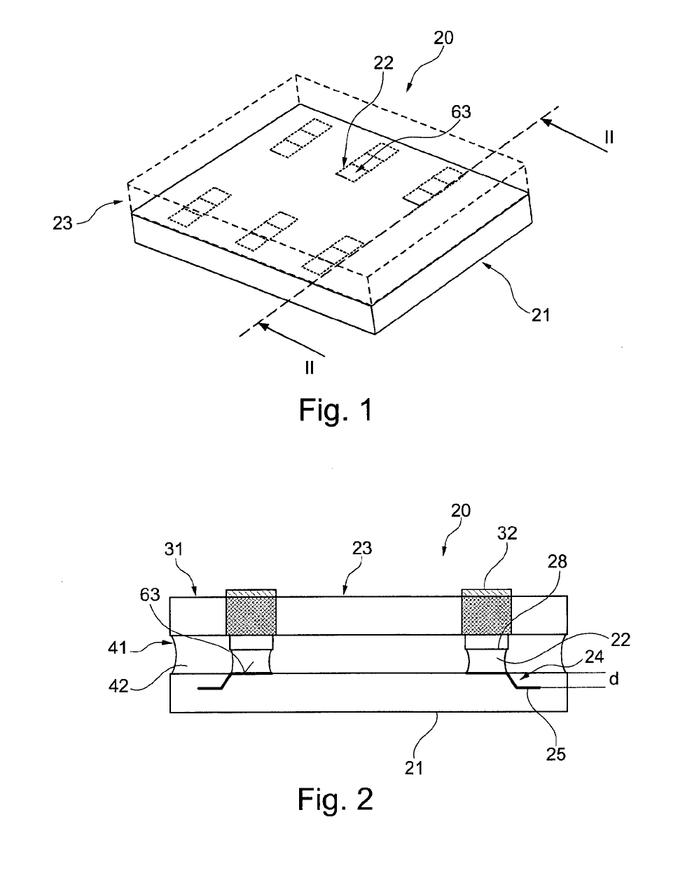

FIG. 1 illustrates a substrate arrangement composed of a semiconductor substrate and a carrier substrate in a perspective view;

FIG. 2 illustrates the substrate arrangement shown in FIG. 1 in a cross-sectional view along intersection line II-II of FIG. 1;

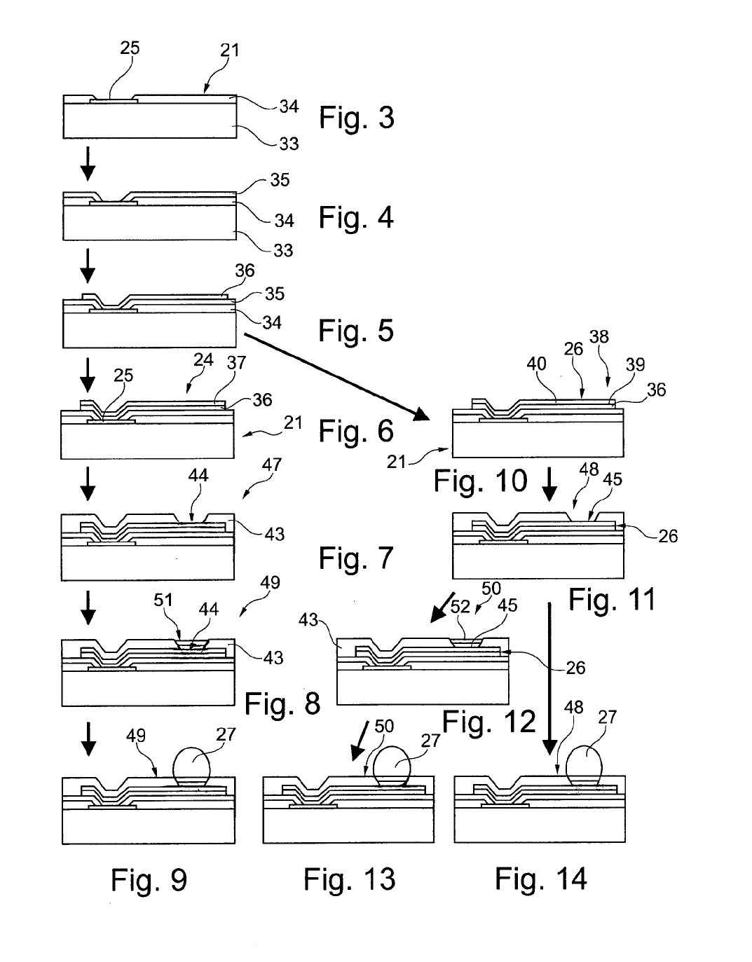

FIG. 3 illustrates a partial view of the semiconductor substrate shown in FIG. 2 having a silicon body which is covered by a passivation layer except for a base terminal face;

FIG. 4 illustrates the semiconductor substrate shown in FIG. 3 having a further passivation layer;

FIG. 5 illustrates the semiconductor substrate having a first contact strip;

FIG. 6 illustrates the semiconductor substrate having a contact arrangement in a first embodiment;

FIG. 7 illustrates the semiconductor substrate having a contact arrangement in a further embodiment;

FIG. 8 illustrates the contact arrangement in a further embodiment;

FIG. 9 illustrates the contact arrangement in a further embodiment;

FIG. 10 illustrates the contact arrangement in a further embodiment;

FIG. 11 illustrates the contact arrangement in a further embodiment;

FIG. 12 illustrates the contact arrangement in a further embodiment;

FIG. 13 illustrates the contact arrangement in a further embodiment;

FIG. 14 illustrates the contact arrangement in a further embodiment;

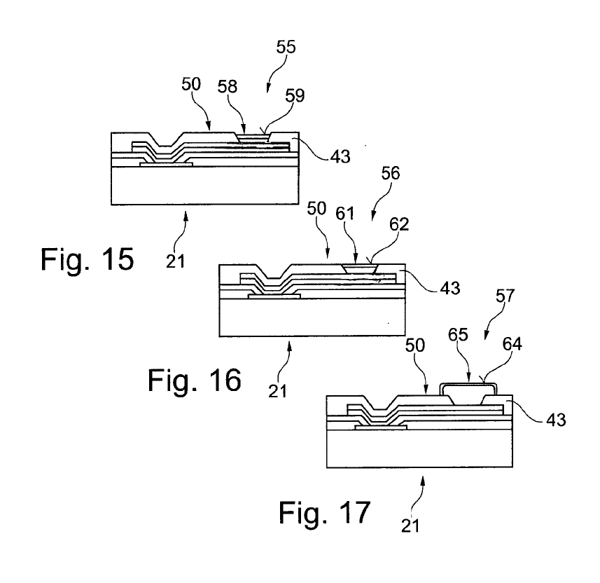

FIG. 15 illustrates the contact arrangement in a further embodiment;

FIG. 16 illustrates the contact arrangement in a further embodiment;

FIG. 17 illustrates the contact arrangement in a further embodiment.

FIG. 1 shows a substrate arrangement 20 having a semiconductor substrate 21 and a carrier substrate 23 which is contacted with the semiconductor substrate 21 via an outer terminal face 22 of the semiconductor substrate 21.

As is shown in particular in FIG. 2, by means of the contact arrangement 24 an inner contact 25 which is formed by a base terminal face of the semiconductor substrate 21 is connected to an outer semiconductor contact 63 of the terminal face arrangement 22 which, in the case of the exemplary embodiment shown in FIG. 2, is formed by a terminal face of the contact arrangement 24 being furnished with a solder bump 27 for connection with a terminal face 28 of the carrier substrate 23.

In the case of the substrate arrangement 20 shown in FIG. 2, the carrier substrate 23 is furnished with via holes 29 which establish an electrically conductive connection between the terminal faces 28 which are arranged on a semiconductor contact side 30 of the carrier substrate 23 and the outer carrier substrate contacts 32 being disposed on an outer contact side 31 of the carrier substrate 23.

FIG. 3 in a partial view shows the semiconductor substrate 21, which in the substrate arrangement 20 according to FIG. 2 is furnished with contact arrangements 24 in the region of an inner contact 25 prior to the formation of a contact arrangement, wherein the semiconductor substrate 21 is substantially composed of a silicon body 33 having an inner contact 25 being disposed thereon and a passivation layer 34 covering the outer edge of the inner contact 25 as well as the surface of the silicon body 33.

To form the contact arrangement 24 illustrated in FIG. 2, according to FIG. 4, a further passivation layer 35 of BCB, PI, PBO or epoxy can be applied, on which, according to FIG. 5, a first, lower contact strip 36 is formed, which may preferably be formed of copper, aluminum or an aluminum alloy, such as AlSi or AlSiCu. It is also possible to form the first, lower contact strip 36 with a layer structure composed of two layers, wherein preferably a titanium layer serves as the base for the aluminum layer or serves as a layer of one of the cited aluminum alloys.

In particular when it comes to ultimately forming a contact arrangement 24 with the smallest possible thickness d (FIG. 2) the interposed formation of the second passivation layer 35 can also be omitted, such that in this case, the first, lower contact strip 36 is directly applied to the passivation layer 34.

As is shown in FIG. 6, to form a contact arrangement 24 as illustrated in FIG. 2, the second, upper contact strip 37 is then formed on the first, lower contact strip 36, wherein the upper contact strip 37, according to FIG. 6, can be formed of a nickel layer which is electrolessly deposited on the lower contract strip 36. To form a contact arrangement 26, as illustrated in FIG. 10, an upper contact strip 38 having a layer structure comprising a first contact strip layer 39 made of nickel and a second contact strip layer 40 made of palladium and being disposed on the first contact strip layer can equally be provided.

In any case, the formation of the contact strip 37 or the contract strip 38 formed by two contact strip layers 39, 40, which have been deposited on top of one another, is carried out in an electroless deposition process, wherein the formation of the contact strip 38 optionally can be performed such that in a first electroless deposition process, a substantially closed nickel layer is produced, and in a second electroless deposition process, a palladium layer is produced which is deposited on the nickel layer. Alternatively, it is also possible to form the contact strip layer of nickel in a discontinuous fashion and to cover the nickel-free regions of the lower contact strip 36 with palladium in the second electroless deposition process.

Independently of the structure of the second, upper contact strip 37 the formation of the contact strip 37 in an electroless deposition process of nickel or nickel and palladium enables an accurate control of the deposition process, such that a desired thickness of the contact strip or the morphology of the contact strip can be realized in order to control the electrical properties of the contact arrangement 24, 26.

Depending on the requirements with respect to the surface structure of the semiconductor substrate 21 the contact arrangements 24, 26 illustrated in FIGS. 6 and 10 can be directly used for producing a substrate arrangement 20, for instance in the case shown in FIG. 2, where spacer metallizations are formed between the semiconductor substrate 21 and the carrier substrate 23 by remelted solder bumps 27, which enable the formation of an insulating gap 41 between the semiconductor substrate 21 and the carrier substrate 23, such that an insulating filler material 42 can be subsequently introduced into the gap 41 so as to seal the substrate arrangement in an insulating fashion.

The following figures show further embodiments of the contact arrangements 47, 48, 49, 50, which on the one hand differ from one another by the application of a further passivation layer 43 for producing a contact area 44, 45 (FIGS. 7 and 11), and on the other hand differ from one another by the formation of an additional contact coating 46 (FIGS. 8 and 12) on the contact area 44, 45.

Hence, FIGS. 7 and 11 show a contact arrangement 47, 48 which, in addition to the contact arrangements 24, 26 (FIGS. 6 and 10), on the upper contact strip 37, 38 features the further passivation layer 43. Here, the formation of the upper contact strip 37, 38 in an electroless deposition process of nickel or nickel and palladium provides for a particularly good adhesion between the contact strips and the passivation layer 43 covering the contact strips in an insulating fashion.

FIGS. 8 and 12 show a contact arrangement 49, 50 which, in addition to the contact arrangements 47, 48 shown in FIGS. 7 and 11, has a contact coating 51, 52 produced on the contact area 44, 45 being defined by the passivation layer 43. The production of the contact coatings 51, 52, in accordance with the above-described production of the respectively upper contact strip 37, 38, is performed by an electroless deposition process for producing a layer structure comprising a lower nickel layer 53 and a gold layer 54 being deposited thereon, wherein the layer structure is directly deposited on the upper contact strip 37 composed of nickel or on the contact strip layer 40 of the contact strip 38 composed of palladium.

FIGS. 9, 13 and 14 show the contact arrangements 49, 50 and 48 in a preparation for producing a substrate arrangement having a solder bump 27 which is then at least partially remelted for producing a contacting with a carrier substrate.

As is shown in FIGS. 15, 16 and 17 with the example of the contact coatings 58, 61, 65 the semiconductor outer contacts 55, 56, 57 can have very different structures.

For instance, FIG. 15 shows the contact coating 58 which forms a contact area 59 being offset with respect to a surface of the passivation layer 43 and thus forms a pocket-shaped contact material receptacle 60.

FIG. 16 shows a contact coating 61 which forms a contact surface 62 being aligned with the surface of the passivation layer 43.

FIG. 17 shows a contact coating 65 which is formed so as to extend beyond the edges of the passivation layer 43, whereby an overall raised contact metallization having a nickel core and a covering layer of palladium is formed with a contact surface 64 protruding beyond the surface of the passivation layer 43.

A combined view of FIGS. 15 to 17 shows that the formation of the contact coatings 58, 61, 65 in an electroless deposition process enables to influence the morphology of the contact coatings, making it possible to conveniently adapt the contact coatings and to form raised contact metallizations by the contact coating 61, which for instance can also be used as a spacer metallization.

1. A contact arrangement for contacting terminal faces of a semiconductor substrate, said arrangement comprising:
at least one inner contact (25) of the contact arrangement that is formed on a substrate surface by a base terminal face of the substrate
a passivation layer covering at least an outer edge region and periphery of the at least one inner contact;
at least one lower contact strip extending laterally away from the at least one inner contact on the passivation layer; and
an upper contact strip formed on the at least one lower contact strip, wherein the upper contact strip is formed by a contact metallization which is substantially composed of a nickel (Ni) layer or a layer structure containing nickel and palladium (Pd).

2. The contact arrangement according to claim 1, in which the Ni layer or the layer structure containing Ni and Pd is formed by autocatalytic deposition of Ni and Pd.

3. The contact arrangement according to claim 1, in which the at least one lower contact strip is formed by a contact metallization which is substantially composed of a layer containing Ti, Al, Cu, AlSl or AlSiCu or of a layer structure containing Ti/Al, Ti/AlCu or Ti/AlSiCu.

4. The contact arrangement according to claim 1, in which an outer contact of the contact arrangement is formed by a contact area of the upper contact strip, wherein the upper contact strip except for the contact area is covered by an outer passivation layer.

5. The contact arrangement according to claim 4, in which the outer passivation layer is formed by a dielectric layer which is essentially composed of BCB, PI, PBO, epoxy or a resist.

6. The contact arrangement according to claim 4, in which the contact area of the upper contact strip is furnished with a contact coating including a Ni/Au layer structure composed of a Ni layer and an Au layer disposed thereon.

7. The contact arrangement according to claim 6, in which the Ni/Au layer structure is formed by autocatalytic deposition of Ni and Au.

8. The contact arrangement according to claim 6, in which a contact surface which is offset with respect to the surface of the passivation layer is formed by the Ni/Au layer structure.

9. The contact arrangement according to claim 6, in which a contact surface which is aligned with the passivation layer is formed by the Ni/Au layer structure.

10. The contact arrangement according to claim 6, in which a contact surface which is formed by the surface of a contact coating being raised with respect to the passivation layer is formed by the Ni/Au layer structure.

11. The contact arrangement according to claim 6, in which the contact coating is furnished with a raised contact made of a solder material.

12. The contact arrangement according to claim 4, in which the contact area is furnished with a contact coating made of a solder material.
